(19) United States
(12) Patent Application Publication
(10) Pub. No.: US 2021/0364875 A1
(43) Pub. Date: Nov. 25, 2021

(54) DISPLAY PANEL AND DISPLAY PANEL MANUFACTURING PROCESS

(71) Applicants: HKC CORPORATION LIMITED, SHENZHEN (CN); CHONGQING HKC OPTOELECTRONICS TECHNOLOGY CO.,LTD., CHONGQING (CN)

(72) Inventor: CHUAN WU, CHONGQING (CN)

(21) Appl. No.: 16/319,484

(22) PCT Filed: Nov. 1, 2018
(86) PCT No.: PCT/CN2018/113322

§ 371 Date: Jan. 22, 2019

(30) Foreign Application Priority Data
Oct. 10, 2018 (CN) 201811178085.7

(51) Int. Cl. G02F 1/1362

(52) U.S. Cl. CPC G02F 1/136286; G02F 1/136222; G02F 1/136227

(57) ABSTRACT

This application discloses a display panel and a display panel manufacturing process. The display panel includes: a first substrate and a second substrate; and an AU ball communicating a common line of the first substrate and a common electrode of the second substrate.

This application claims priority to Chinese Patent Application No. 201811178085.7, filed with the Chinese Patent Office on Oct. 10, 2018 and entitled “DISPLAY PANEL AND DISPLAY PANEL MANUFACTURING PROCESS”, which is incorporated herein by reference in its entirety.

### TECHNICAL FIELD

This application relates to the field of display technologies, more particularly to a display panel and a display panel manufacturing process.

### BACKGROUND

The description herein provides only background information related to this application, but does not necessarily constitute the existing technology.

Display panels have gradually become the mainstream of the market at present due to the excellent characteristics of high image quality, good space utilization efficiency, low power consumption, no radiation, etc.

In a LCD (Liquid Crystal Display) of VA (VerticalAlignment) technology, liquid crystal is rotated by a vertical electric field loaded and formed between a color filter substrate and an array substrate, so that the liquid crystal has different deflection angles, and an upper polarizer can transmit light with different intensities. During the electric field loading process, the electric field on the color filter substrate guides signals from the array substrate to the color filter substrate by a TransferPad. A circle of reticular common electrode trace of a first metal layer and a second metal layer is usually arranged on the circumference of a panel, and the TransferPad is designed at a suitable position. The TransferPad is formed by laying a transparent conductive layer on the upper surface of the first metal layer or the upper surfaces of the first metal layer and the second metal layer. During the actual operating process of the panel, common electrode signals transmitted by the first metal layer are finally transmitted to a common electrode of the color filter substrate by passing an AU ball through the first metal layer at the TransferPad, and transmitted from the array substrate to the color filter substrate.

However, in a NarrowBorder product, due to the limitation of a manufacturing process, the AU ball (formed by dotting) often deviates from the designed TransferPad, causing Mura.

### SUMMARY

This application provides a display panel and a display panel manufacturing process to avoid the edge of a display area from being raised so as to improve the production yield of the panel.

To achieve the above objective, this application provides a display panel, comprising:

a first substrate;

a second substrate opposite to the first substrate;

the first substrate comprising a common line, and the second substrate comprising a common electrode;

an AU ball, arranged in a non-display area of the display panel to conduct the common line of the first substrate and the common electrode of the second substrate, the AU ball being arranged at a TransferPad;

a first connection area, connected with the TransferPad and close to a display area of the display panel;

a second connection area, located on the periphery of the TransferPad;

the first substrate comprising:

a substrate;

a first metal layer covering a first surface of the substrate;

a gate insulating layer, arranged on a first surface of the first metal layer, the gate insulating layer being hollowed out corresponding to the TransferPad to form a gate insulating sunken area;

a second metal layer, arranged only on a first surface of the gate insulating layer at the second connection area;

a passivation layer, arranged on the first surface of the gate insulating layer at the first connection area, and a first surface of the second metal layer at the second connection area, and a position of the passivation layer corresponding to the gate insulating sunken area being hollowed out;

a transparent electrode layer, arranged at a position of the first metal layer corresponding to the TransferPad, and covering at least a side wall, corresponding to the TransferPad, of the passivation layer at the first connection area, as well as side walls of the gate insulating layer, the second metal layer and the passivation layer at the second connection area;

the AU ball being arranged on a first surface of the transparent electrode layer, and communicating the common line of the first substrate and the common electrode of the second substrate.

This application discloses a display panel, comprising:

an array substrate;

a color filter substrate opposite to the array substrate;

the array substrate comprising a common line, and the color filter substrate comprising a common electrode;

an AU ball, arranged in a non-display area of the display panel to conduct the common line of the array substrate and the common electrode of the color filter substrate, the AU ball being arranged at a TransferPad;

a first connection area, connected with the TransferPad and close to a display area of the display panel;

a second connection area, located on the periphery of the TransferPad;

the array substrate comprising:

a substrate;

a first metal layer covering a first surface of the substrate;

a gate insulating layer, arranged on a first surface of the first metal layer, the gate insulating layer being hollowed out corresponding to the TransferPad to form a gate insulating sunken area;

a second metal layer, arranged only on a first surface of the gate insulating layer at the second connection area;

a passivation layer, arranged on the first surface of the gate insulating layer at the first connection area, and a first surface of the second metal layer at the second connection area, and a position of the passivation layer corresponding to the gate insulating sunken area being hollowed out;

a transparent electrode layer, arranged at a position of the first metal layer corresponding to the TransferPad, and covering at least a side wall, corresponding to the TransferPad, of the passivation layer at the first connection area, as well as side walls of the gate insulating layer, the second metal layer and the passivation layer at the second connection area;

the AU ball being arranged on a first surface of the transparent electrode layer, and communicating the common line of the array substrate and the common electrode of the color filter substrate.

The first metal layer and the common line of the array substrate are made through a same photomask and electrically connected with each other.

This application further discloses a display panel manufacturing process, comprising the steps of:

covering the upper surface of a substrate with a metal material layer, and etching the metal material layer to form a first metal layer;

forming a gate insulating layer on a first surface of the first metal layer, and etching a portion of the gate insulating layer corresponding to a TransferPad to form a gate insulating sunken area;

forming a second metal layer on a first surface of the gate insulating layer, and etching the second metal layer at a first connection area and the TransferPad;

forming a passivation layer on the first surface of the gate insulating layer at the first connection area and a first surface of the second metal layer at a second connection area, and etching a portion of the gate insulating layer corresponding to the TransferPad;

forming a transparent electrode layer on the first surface of the first metal layer corresponding to the TransferPad, and enabling the transparent electrode layer to simultaneously cover side walls, corresponding to the TransferPad, of the passivation layer and the gate insulating layer at the first connection area, as well as side walls, corresponding to the TransferPad, of the passivation layer, the second metal layer and the gate insulating layer at the second connection area, the transparent electrode layer communicating with the common line to form a first substrate;

forming a second substrate provided with a common electrode;

arranging an AU ball on a first surface of the transparent electrode layer, and enabling the AU ball to communicate the common line of the first substrate and the common electrode of the second substrate.

In a LCD of VA (VerticalAlignment) technology, liquid crystal is rotated by a vertical electric field loaded and formed between the color filter substrate and the array substrate, so that the liquid crystal has different deflection angles, and an upper polarizer transmits light with different intensities. During the electric field loading process, the electric field on the color filter substrate guides signals from the array substrate to the color filter substrate by the TransferPad. A circle of reticular VCOM (Common Electrode) trace of the first metal layer and the second metal layer is usually arranged on the circumference of the panel, and the TransferPad is designed at a suitable position. The second metal layer is not arranged at the TransferPad, and the transparent electrode layer is laid on the first surface of the first metal layer to form the TransferPad. During the actual operating process of the panel, VCOM signals transmitted by the first metal layer are transmitted from the first metal layer to the transparent electrode layer at the TransferPad and finally transmitted to the transparent electrode layer of the CF (ColorFilter) by the AU ball, that is, transmitted from the array substrate to the CF substrate. However, in a NarrowBorder product, due to the limitation of a manufacturing process, the AU ball (formed by dotting) often deviates from the designed TransferPad, so that the AU ball deviates to the first connection area, and is even formed on the first surfaces of the first metal layer and the second metal layer at the first connection area, so that the TransferPad is closer to the display area, the box thickness of the edge of the display area is raised and Mura appears. In this solution, the second metal layer is arranged only on the first surface of the gate insulating layer at the second connection area, the second metal layer at the first connection area is etched away to reduce the total film thickness of the first connection area, and in this way, even if part of the AU ball deviates to the first connection area, there may be sufficient space to accommodate the AU ball, thereby reducing the edge of the display area raised by the AU ball, avoiding the Mura caused by the raised edge of the display area, improving the display effect of a display panel, and improving the production yield of the display panel, especially the NarrowBorder display panel.

### BRIEF DESCRIPTION OF DRAWINGS

The accompanying drawings included are used for helping understand the embodiments of this application, constitute a part of this specification, illustrate examples of the embodiments of this application and, together with the description, serve to explain the principles of this application. Apparently, the accompanying drawings in the following description merely show some embodiments of this application, and persons of ordinary skill in the art may still derive other drawings from these accompanying drawings without creative effort. In the figures:

FIG. 1 is a schematic diagram of a basic structure of a display panel according to an embodiment of this application.

FIG. 2 is an enlarged schematic diagram of an A-A′ area in FIG. 1 according to an embodiment of this application.

FIG. 3 is a cross-sectional schematic diagram of the A-A′ area in FIG. 1.

FIG. 4 is a schematic structural diagram of a display panel according to an embodiment of this application.

FIG. 5 is a schematic structural diagram of a display panel according to another embodiment of this application.

FIG. 6 is a flow diagram of a method for a display panel according to an embodiment of this application.

### DETAILED DESCRIPTION

Specific structures and functional details disclosed herein are merely representative, and are intended to describe the objectives of the exemplary embodiments of this application. However, this application may be specifically implemented in many alternative forms, and should not be construed as being limited to the embodiments set forth herein.

In the description of this application, it should be understood that orientation or position relationships indicated by the terms such as “center”, “transverse”, “on”, “below”, “left”, “right”, “vertical”, “horizontal”, “top”, “bottom”, “inside”, and “outside” are based on orientation or position relationships shown in the accompanying drawings, and are used only for ease and brevity of illustration and description, rather than indicating or implying that the mentioned apparatus or component must have a particular orientation or must be constructed and operated in a particular orientation. Therefore, such terms should not be construed as limiting of this application. In addition, the terms such as “first” and “second” are used only for the purpose of description, and should not be understood as indicating or implying the relative importance or implicitly specifying the number of the indicated technical features. Therefore, a feature defined by “first” or “second” can explicitly or implicitly include one or more of said features. In the description of this application, unless otherwise stated, “a plurality of” means two or more than two. In addition, the terms “include”, “comprise” and any variant thereof are intended to cover non-exclusive inclusion.

In the description of this application, it should be noted that unless otherwise explicitly specified or defined, the terms such as “mount”, “install”, “connect”, and “connection” should be understood in a broad sense. For example, the connection may be a fixed connection, a detachable connection, or an integral connection; or the connection may be a mechanical connection or an electrical connection; or the connection may be a direct connection, an indirect connection through an intermediary, or internal communication between two components. Persons of ordinary skill in the art may understand the specific meanings of the foregoing terms in this application according to specific situations.

The terminology used herein is for the purpose of describing specific embodiments only and is not intended to be limiting of exemplary embodiments. As used herein, the singular forms “a”, “an” and “the” are intended to include the plural forms as well, unless the context clearly indicates otherwise. It should be further understood that the terms “include” and/or “comprise” when used in this specification, specify the presence of stated features, integers, steps, operations, elements, and/or components, but do not preclude the presence or addition of one or more other features, integers, steps, operations, elements, components, and/or combinations thereof.

A first surface corresponds to, for example, an upper surface.

Hereinafter, this application is further illustrated in conjunction with the drawings and alternative embodiments.

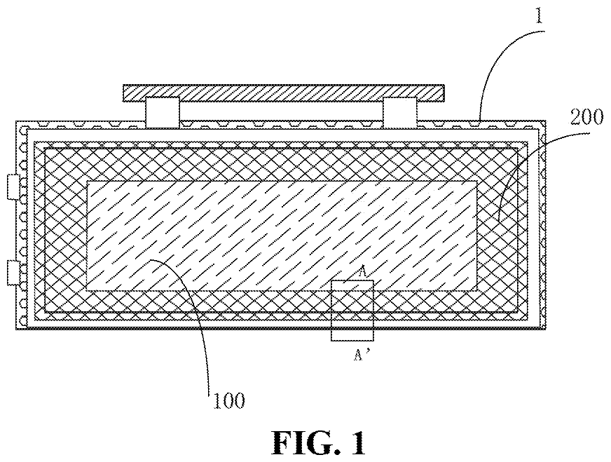

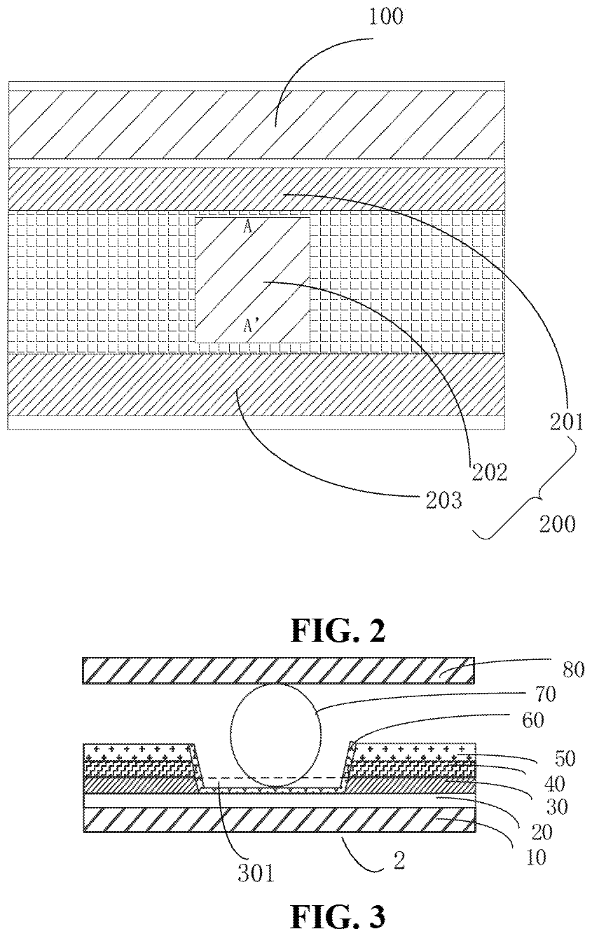

As shown in FIG. 1 to FIG. 5, an embodiment of this application discloses a display panel, including:

a first substrate 2, and a second substrate 80 opposite to the first substrate 2; the first substrate 2 including a common line, and the second substrate 80 including a common electrode;

an AU ball, arranged m a non-display area of the display panel to conduct the common line of the first substrate 2 and the common electrode of the second substrate 80, the AU ball being arranged at a TransferPad;

a first connection area 201, connected with the TransferPad and close to a display area 100 of the display panel;

a second connection area 203, located on the periphery of the TransferPad 202;

the first substrate 2 including:

a substrate 10:

a first metal layer 20 covering a first surface of the substrate 10;

a gate insulating layer 30, arranged on a first surface of the first metal layer 20, the gate insulating layer 30 being hollowed out corresponding to the TransferPad 202 to form a gate insulating sunken area 301;

a second metal layer 40, arranged only on a first surface of the gate insulating layer 30 at the second connection area 203; a passivation layer 50, arranged on the first surface of the gate insulating layer 30 at the first connection area 201, and a first surface of the second metal layer 40 at the second connection area 203, and a position of the passivation layer 50 corresponding to the gate insulating sunken area 301 being hollowed out;

a transparent electrode layer 60, arranged at a position of the first metal layer 20 corresponding to the TransferPad 202, and covering at least a side wall, corresponding to the TransferPad 202, of the passivation layer 50 at the first connection area 201, as well as side walls of the gate insulating layer 30, the second metal layer 40 and the passivation layer 50 at the second connection area 203;

the array substrate including a common line, and the color filter substrate including a common electrode;

the AU ball 70 being arranged on a first surface of the transparent electrode layer 60, and communicating the common line of the first substrate 2 and the common electrode of the second substrate 80.

The first substrate 2 is an array substrate, and the second substrate 80 is a color filter substrate.

In a LCD of VA (VerticalAlignment) technology, liquid crystal is rotated by a vertical electric field loaded and formed between the color filter substrate and the array substrate, so that the liquid crystal has different deflection angles, and an upper polarizer transmits light with different intensities. During the electric field loading process, the electric field of the second substrate 80 guides signals from the array substrate to the second substrate 80 by the TransferPad 202. A circle of reticular VCOM trace of the first metal layer 20 and the second metal layer 40 is usually arranged on the circumference of the panel, and the TransferPad 202 is designed at a suitable position. The second metal layer 40 is not arranged at the TransferPad 202, and the transparent electrode layer 60 is laid on the first surface of the first metal layer 20 to form the TransferPad 202. During the actual operating process of the panel, VCOM signals transmitted by the first metal layer 20 are transmitted from the first metal layer 20 to the transparent electrode layer 60 at the TransferPad 202 and finally transmitted to the transparent electrode layer 60 of the CF by the AU ball 70, that is, transmitted from the array substrate to the color filter substrate. However, in a Narrow Border product, due to the limitation of a manufacturing process, the AU ball 70 (formed by dotting) often deviates from the designed TransferPad 202, so that the AU ball 70 deviates to the first connection area 201, and is even formed on the first surfaces of the first metal layer 20 and the second metal layer 40 at the first connection area 201, so that the TransferPad 202 is closer to the display area 100, the box thickness of the edge of the display area 100 is raised and Mura appears. In this solution, the second metal layer 40 is arranged only on the first surface of the gate insulating layer 30 at the second connection area 203, the second metal layer 40 at the first connection area 201 is etched away to reduce the total film thickness of the first connection area 201, and in this way, even if part of the AU ball 70 deviates to the first connection area 201, there may be sufficient space to accommodate the AU ball 70, thereby reducing the edge of the display area 100 raised by the AU ball 70, avoiding the Mura caused by the raised edge of the display area 100, improving the display effect of a display panel 1, and improving the production yield of the display panel 1, especially the Narrow Border display panel 1.

The common line is a COM electrode of the non-display area 200 of the array substrate, and the common electrode is a CF electrode of the color filter substrate.

Particularly, the second metal layer 40 is arranged in such a way only when being correspondingly arranged at the TransferPad 202 of the AU ball 70.

According to an embodiment of this application, the first metal layer 20 is hollowed out corresponding to the first connection area 201.

The portion of the first metal layer 20 located at the first connection area 201 is etched away to prevent light leakage that may occur due to raising of the AU ball 70 and uneven box formation.

According to an embodiment of this application, the first metal layer 20 and the common line of the non-display area 200 of the array substrate are made through a same photomask and electrically connected with each other.

The first metal layer 20 and the common line of the array substrate are made through a same process, and the electrodes are connected without perforating, which simplifies the process.

According to an embodiment of this application, the second metal layer 40 and the common line of the non-display area 200 of the array substrate are made through a same photomask and electrically connected with each other.

The second metal layer 40 and the common line of the non-display area 200 of the array substrate are made through a same process, and the electrodes are connected without perforating, which simplifies the process.

According to an embodiment of this application, the common line of the array substrate and the first metal layer 20 or the second metal layer 40 are made through a same photomask, and the first metal layer 20 and the second metal layer 40 are electrically connected with each other through a via hole.

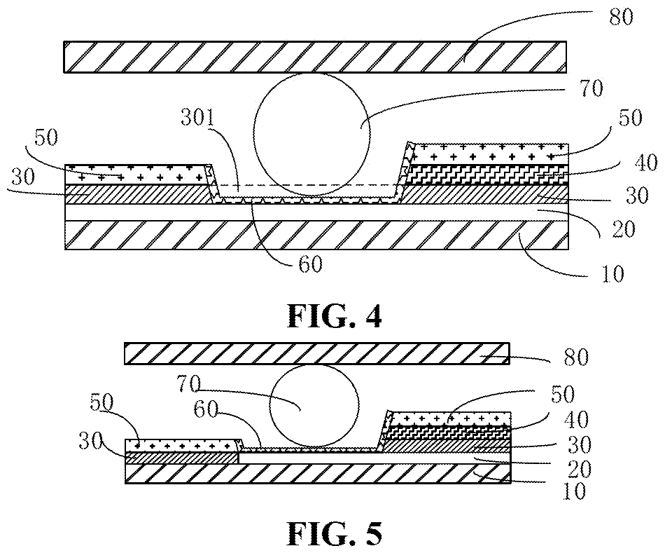

As another embodiment of this application, referring to FIG. 4, disclosed is a display panel, including:

an array substrate, and a color filter substrate opposite to the array substrate; the array substrate including a common line, and the color filter substrate including a common electrode;

an AU ball 70, arranged in a non-display area 200 of the display panel to conduct the common line of the array substrate and the common electrode of the color filter substrate, the AU ball being arranged at a TransferPad;

a first connection area 201, connected with the TransferPad 202 and close to a display area 100 of the display panel;

a second connection area 203, located on the periphery of the TransferPad 202;

the array substrate including:

a substrate 10;

a first metal layer 20 covering a first surface of the substrate 10;

a gate insulating layer 30, arranged on a first surface of the first metal layer 20, the gate insulating layer 30 being hollowed out corresponding to the TransferPad 202 to form a gate insulating sunken area 301;

a second metal layer 40, arranged only on a first surface of the gate insulating layer 30 at the second connection area 203;

a passivation layer 50, arranged on the first surface of the gate insulating layer 30 at the first connection area 201, and a first surface of the second metal layer 40 at the second connection area 203, and a position of the passivation layer 50 corresponding to the gate insulating sunken area 301 being hollowed out;

a transparent electrode layer 60, arranged at a position of the first metal layer 20 corresponding to the TransferPad 202, and covering at least a side wall, corresponding to the TransferPad 202, of the passivation layer 50 at the first connection area 201, as well as side walls of the gate insulating layer 30, the second metal layer 40 and the passivation layer 50 at the second connection area 203;

the AU ball 70 being arranged on a first surface of the transparent electrode layer 60, and communicating the common line of the array substrate and the common electrode of the color filter substrate;

the first metal layer 20 and the common line of the array substrate being made through a same photomask and electrically connected with each other.

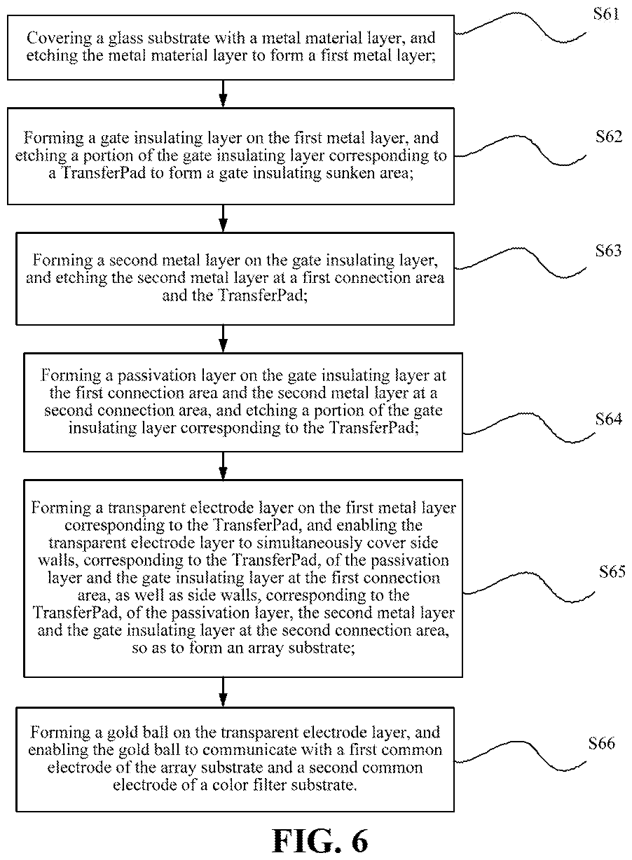

As another embodiment of this application, referring to FIG. 6, disclosed is a manufacturing process of the display panel 1, including:

S61: covering a substrate 10 with a metal material layer, and etching the metal material layer to form a first metal layer 20 and a common line;

S62: forming a gate insulating layer 30 on a first surface of the first metal layer 20, and etching a portion of the gate insulating layer 30 corresponding to a TransferPad 202 to form a gate insulating sunken area 301;

S63: forming a second metal layer 40 on a first surface of the gate insulating layer 30, and etching the second metal layer 40 at a first connection area 201 and the TransferPad 202;

S64: forming a passivation layer 50 on the first surface of the gate insulating layer 30 at the first connection area 201 and a first surface of the second metal layer 40 at a second connection area 203, and etching a portion of the gate insulating layer 30 corresponding to the TransferPad 202;

S65: forming a transparent electrode layer 60 on the first surface of the first metal layer 20 corresponding to the TransferPad 202, and enabling the transparent electrode layer 60 to simultaneously cover side walls, corresponding to the TransferPad 202, of the passivation layer 50 and the gate insulating layer 30 at the first connection area 201, as well as side walls, corresponding to the TransferPad 202, of the passivation layer 50, the second metal layer 40 and a side wall of the gate insulating layer 30 at the second connection area 203, the transparent electrode layer communicating with the common line to form an array substrate;

forming a color filter substrate provided with a common electrode;

S66: forming an AU ball 70 on a first surface of the transparent electrode layer 60, and enabling the AU ball 70 to communicate the common line of the array substrate and the common electrode of the second substrate 80.

In a LCD of VA (VerticalAlignment) technology, liquid crystal is rotated by a vertical electric field loaded and formed between the color filter substrate and the array substrate, so that the liquid crystal has different deflection angles, and an upper polarizer transmits light with different intensities. During the electric field loading process, the electric field on the second substrate 80 guides signals from the array substrate to the second substrate 80 by the TransferPad 202. A circle of reticular VCOM trace of the first metal layer 20 and the second metal layer 40 is usually arranged on the circumference of the panel, and the TransferPad 202 is designed at a suitable position. The second metal layer 40 is not arranged at the TransferPad 202, and the transparent electrode layer 60 is laid on the first metal layer 20 to form the TransferPad 202. During the actual operating process of the panel, common voltage signals transmitted by the first metal layer 20 are transmitted from the first metal layer 20 to the transparent electrode layer 60 at the TransferPad 202 and finally transmitted to the transparent electrode layer 60 of the CF by the AU ball 70, that is, transmitted from the array substrate to the color filter substrate. However, in a Narrow Border product, due to the limitation of a manufacturing process, the AU ball 70 (formed by dotting) often deviates from the designed TransferPad 202, so that the AU ball 70 deviates to the first connection area 201, and is even formed on the first surfaces of the first metal layer 20 and the second metal layer 40 at the first connection area 201, so that the TransferPad 202 is closer to the display area 100, the box thickness of the edge of the display area 100 is raised and Mura appears. In this solution, the second metal layer 40 is arranged only on the first surface of the gate insulating layer 30 at the second connection area 203, the second metal layer 40 at the first connection area 201 is etched away to reduce the total film thickness of the first connection area 201, and in this way, even if part of the AU ball 70 deviates to the first connection area 201, there may be sufficient space to accommodate the AU ball 70, thereby reducing the edge of the display area 100 raised by the AU ball 70, avoiding the Mura caused by the raised edge of the display area 100, improving the display effect of the display panel 1, and improving the production yield of the display panel 1, especially the Narrow Border display panel 1.

According to an embodiment of this application, the step of forming the first metal layer 20 on the metal material layer further includes: etching away the portion of the first metal layer 20 corresponding to the first connection area 201.

The portion of the first metal layer 20 located at the first connection area 201 is etched away to prevent light leakage that may occur due to raising of the AU ball 70 and uneven box formation.

If the thickness of the gate insulating layer 30 is smaller than or equal to that of the first metal layer 20, the transparent electrode layer 60 does not cover the side wall of the gate insulating layer 30 corresponding to the TransferPad 202. If the thickness of the gate insulating layer 30 is greater than that of the first metal layer 20, the transparent electrode layer 60 covers the upper part of the side wall of the gate insulating layer 30 corresponding to the TransferPad 202.

According to an embodiment of this application, the first metal layer 20 and the common line of the array substrate are made through a same process and electrically connected with each other.

The first metal layer 20 and the common line of the array substrate are made through the same process, and the electrodes are connected without perforating, which simplifies the process.

According to an embodiment of this application, the second metal layer 40 and the common line of the array substrate are made through a same process and electrically connected with each other.

The second metal layer 40 and the common line of the array substrate are made through the same process, and the electrodes are connected without perforating, which simplifies the process.

According to an embodiment of this application, the common line of the array substrate and the first metal layer 20 or the second metal layer 40 are made through a same photomask, and the first metal layer 20 and the second metal layer 40 are electrically connected with each other through a via hole.

The first metal layer 20 and the second metal layer 40 are electrically connected with each other through the via hole so as to reduce the possibility of an open circuit due to disconnection. When the common line of the array substrate and the first metal layer 20 are on the same layer and are electrically connected with each other, the second metal layer 40 is insulated from the second metal layer 40 of the display area 100. When the common line and the second metal layer 40 are on the same layer and are electrically connected with each other, the first metal layer 20 is insulated from the first metal layer 20 of the display area 100 so as to prevent crosstalk.

The display panel of this application may be a twisted nematic (TN) panel, an in-plane switching (IPS) panel, or a multi-domain vertical alignment (VA) panel, and may certainly be any other suitable type of panel.

The foregoing contents are detailed descriptions of this application in conjunction with specific optional embodiments, and it should not be considered that the specific implementation of this application is limited to these descriptions. Persons of ordinary skill in the art can further make simple deductions or replacements without departing from the concept of this application, and such deductions or replacements should all be considered as falling within the protection scope of this application.

What is claimed is:

1. A display panel, comprising:
a first substrate;
a second substrate opposite to the first substrate;
the first substrate comprising a common line, and the second substrate comprising a common electrode;
an AU ball, arranged in a non-display area of the display panel to conduct the common line of the first substrate and the common electrode of the second substrate, the AU ball being arranged at a TransferPad;
a first connection area, connected with the TransferPad and close to a display area of the display panel;
a second connection area, located on the periphery of the TransferPad;
the first substrate comprising:
a substrate;
a first metal layer covering a first surface of the substrate;
a gate insulating layer, arranged on a first surface of the first metal layer, the gate insulating layer being hollowed out corresponding to the TransferPad to form a gate insulating sunken area;
a second metal layer, arranged only on a first surface of the gate insulating layer at the second connection area;
a passivation layer, arranged on the first surface of the gate insulating layer at the first connection area, and a first surface of the second metal layer at the second connection area, and a position of the passivation layer corresponding to the gate insulating sunken area being hollowed out;
a transparent electrode layer, arranged at a position of the first metal layer corresponding to the TransferPad, and covering at least a side wall, corresponding to the TransferPad, of the passivation layer at the first connection area, as well as side walls of the gate insulating layer, the second metal layer and the passivation layer at the second connection area; and
the AU ball being arranged on a first surface of the transparent electrode layer, and communicating the common line of the first substrate and the common electrode of the second substrate.

2. The display panel of claim 1, wherein a position of the first metal layer corresponding to the first connection area is hollowed out.

3. The display panel of claim 1, wherein the first metal layer and the common line of the first substrate are made through a same photomask and electrically connected with each other.

4. The display panel of claim 1, wherein the second metal layer and the common line of the first substrate are made through a same photomask and electrically connected with each other.

5. The display panel of claim 1, wherein the common line of the first substrate and the first metal layer or the second metal layer are made through a same photomask.

6. The display panel of claim 5, wherein the first metal layer and the second metal layer are electrically connected with each other through a via hole.

7. The display panel of claim 1, wherein the first substrate is an array substrate, and the second substrate is a color filter substrate.

8. A display panel, comprising:
an array substrate;
a color filter substrate opposite to the array substrate;
the array substrate comprising a common line, and the color filter substrate comprising a common electrode; And
an AU ball, arranged in a non-display area of the display panel to conduct the common line of the array substrate and the common electrode of the color filter substrate, the AU ball being arranged at a TransferPad;
a first connection area, connected with the TransferPad and close to a display area of the display panel;
a second connection area, located on the periphery of the TransferPad;
the array substrate comprising:
a substrate;
a first metal layer covering a first surface of the substrate;
a gate insulating layer, arranged on a first surface of the first metal layer, the gate insulating layer being hollowed out corresponding to the TransferPad to form a gate insulating sunken area;
a second metal layer, arranged only on a first surface of the gate insulating layer at the second connection area;
a passivation layer, arranged on the first surface of the gate insulating layer at the first connection area, and a first surface of the second metal layer at the second connection area, and a position of the passivation layer corresponding to the gate insulating sunken area being hollowed out;
a transparent electrode layer, arranged at a position of the first metal layer corresponding to the TransferPad, and covering at least a side wall, corresponding to the TransferPad, of the passivation layer at the first connection area, as well as side walls of the gate insulating layer, the second metal layer and the passivation layer at the second connection area; and
the AU ball being arranged on a first surface of the transparent electrode layer, and communicating the common line of the array substrate and the common electrode of the color filter substrate.

9. A display panel manufacturing process, comprising the steps of:
forming a first substrate provided with a common line;
forming a second substrate provided with a common electrode; and
arranging an AU ball between the first substrate and the second substrate, the AU ball communicating the common line of the first substrate and the common electrode of the second substrate.

10. The display panel manufacturing process of claim 9, wherein the step of forming a first substrate provided with a common line comprises:
covering a substrate with a metal material layer, and etching the metal material layer to form a first metal layer and a common line;
forming a gate insulating layer on a first surface of the first metal layer, and etching a portion of the gate insulating layer corresponding to a TransferPad to form a gate insulating sunken area;
forming a second metal layer on a first surface of the gate insulating layer, and etching the second metal layer at a first connection area and the TransferPad;
forming a passivation layer on the first surface of the gate insulating layer at the first connection area and a first surface of the second metal layer at a second connection area, and etching a portion of the gate insulating layer corresponding to the TransferPad;
forming a transparent electrode layer on the first surface of the first metal layer corresponding to the TransferPad, and enabling the transparent electrode layer to simultaneously cover side walls of the passivation layer and the gate insulating layer corresponding to the TransferPad at the first connection area, as well as side walls of the passivation layer, the second metal layer and the gate insulating layer corresponding to the TransferPad at the second connection area, the transparent electrode layer communicating with the common line to form a first substrate.

11. The display panel manufacturing process of claim 10, wherein in the step of arranging an AU ball between the first substrate and the second substrate, the AU ball communicating the common line of the first substrate and the common electrode of the second substrate, the AU ball is arranged on the first surface of the transparent electrode layer.

12. The display panel manufacturing process of claim 9, wherein the first substrate is an array substrate, and the second substrate is a color filter substrate.

13. The display panel manufacturing process of claim 10, wherein the step of covering a substrate with a metal material layer, and etching the metal material layer to form a first metal layer and a common line further comprises: etching the portion of the first metal layer corresponding to the first connection area.

14. The display panel manufacturing process of claim 10, wherein the first metal layer and the common line of the first substrate are made through a same process and electrically connected with each other.

15. The display panel manufacturing process of claim 10, wherein the second metal layer and the common line of the first substrate are made through a same process and electrically connected with each other.

16. The display panel manufacturing process of claim 10, wherein the common line of the first substrate and the first metal layer or the second metal layer are made through a same photomask.

17. The display panel manufacturing process of claim 16, wherein the first metal layer and the second metal layer are electrically connected with each other through a via hole.
